(19) United States
(12) Patent Application Publication
(10) Pub. No.: US 2017/0235634 A1
(43) Pub. Date: Aug. 17, 2017

(54) SEMICONDUCTOR DEVICES AND SEMICONDUCTOR SYSTEMS INCLUDING THE SAME

(71) Applicant: SK hynix Inc., Icheon-si Gyeonggi-do (KR)

(72) Inventor: Chang Hyun KIM, Seoul (KR)

(21) Appl. No.: 15/175,370

(22) Filed: Jun. 7, 2016

(30) Foreign Application Priority Data
Feb. 15, 2016 (KR) 10-2016-0017188

(51) Int. Cl. G06F 11/10; G06F 3/06; G11C 7/10; G11C 7/00; G11C 29/52

(52) U.S. Cl. CPC G06F 11/1068; G11C 7/00; G11C 29/52; G11C 7/10; G06F 3/0619; G06F 3/064; G06F 3/0688

(57) ABSTRACT

A semiconductor device may be provided. The semiconductor device may include an error correction control circuit and a signal storage circuit. The error correction control circuit may be configured to generates first to (P+1)^{th} write parity signals from first to M^{th} write data signals based on a test mode signal and a read/write signal. Each of the first to (P+1)^{th} write parity signals may be generated by performing a logical operation on at least two write data signals of the first to M^{th} write data signals. The signal storage circuit may be configured to store the first to M^{th} write data signals and the first to (P+1)^{th} write parity signals based on the read/write signal.

### CROSS-REFERENCE TO RELATED APPLICATIONS

The present application claims priority under 35 U.S.C 119(a) to Korean Patent Application No. 10-2016-0017188, filed on Feb. 15, 2016, which is incorporated herein by reference in its entirety.

### BACKGROUND

1. Technical Field

Embodiments of the present disclosure generally relate to semiconductor devices configured to correct errors of read data and semiconductor systems including the same.

2. Related Art

As semiconductor memory devices are scaled down and designed to operate at high speeds, errors occurring during a write operation and a read operation of the semiconductor memory devices may increase. An error check correction (ECC) circuit may be used to sense and correct the errors. The ECC circuit may generate parity signals of data signals which are written into the semiconductor memory device. The ECC circuit may correct errors of data signals which are read out according to the parity signals to output the corrected data signals.

### SUMMARY

According to an embodiment, a semiconductor device may be provided. The semiconductor device may include an error correction control circuit and a signal storage circuit. The error correction control circuit may be configured to generate first to (P+1)^{th} write parity signals from first to M^{th} write data signals based on a test mode signal and a read/write signal. Each of the first to (P+1)^{th} write parity signals may be generated by performing a logical operation on at least two write data signals of the first to M^{th} write data signals. The signal storage circuit may be configured to store the first to M^{th} write data signals and the first to (P+1)^{th} write parity signals based on the read/write signal. M may be a natural number and P may be a natural number.

According to an embodiment, a semiconductor device may be provided. The semiconductor device may include an error correction control circuit and an error sensing circuit. The error correction control circuit may be configured to generate first to (P+1)^{th} syndrome signals from first to M^{th} read data signals and first to (P+1)^{th} read parity signals based on a test mode signal and a read/write signal. Each of the first to (P+1)^{th} syndrome signals may be generated by performing a logical operation on at least two of the first to M^{th} read data signals and one of the first to (P+1)^{th} read parity signals. The number of the read data signals used in the logical operation for generating each of the first to (P+1)^{th} syndrome signals may be an odd number. The error sensing circuit may be configured to generate an error sensing signal according to a logic level combination of the first to (P+1)^{th} syndrome signals.

According to an embodiment, a semiconductor system may be provided. The semiconductor system may include a first semiconductor device and a second semiconductor device. The first semiconductor device may be configured to receive or output a data signal and receive an error sensing signal. The second semiconductor device may be configured to generate first to (M−1)^{th} write data signals from the data signal, generate an M^{th} write data signal fixed at a first logic level, generate first to (P+1)^{th} write parity signals from the first to M^{th} write data signals based on a test mode signal and a read/write signal, and generate the error sensing signal if an error occurs in first to (M−1)^{th} read data signals and first to (P+1)^{th} read parity signals which are outputted after the first to (M−1)^{th} write data signals and the first to (P+1)^{th} write parity signals are stored. Each of the first to (P+1)^{th} write parity signals may be generated by performing a logical operation on at least two of the first to M^{th} write data signals. The number of the write data signals used in the logical operation for generating each of the first to (P+1)^{th} write parity signals may be an odd number.

### BRIEF DESCRIPTION OF THE DRAWINGS

FIG. 1 is a block diagram illustrating a representation of an example of a configuration of a semiconductor system according to an embodiment of the present disclosure.

FIG. 2 is a block diagram illustrating a representation of an example of an error correction control circuit included in the semiconductor system of FIG. 1.

FIG. 3 is a block diagram illustrating a representation of an example of an error correction arithmetic circuit included in the error correction control circuit of FIG. 2.

FIG. 4 is a circuit diagram illustrating a representation of an example of an additional data signal generation circuit included in the error correction arithmetic circuit of FIG. 3.

FIG. 5 is a circuit diagram illustrating a representation of an example of a parity signal input control circuit included in the error correction arithmetic circuit of FIG. 3.

FIG. 6 is a block diagram illustrating a representation of an example of a configuration of a semiconductor system according to an embodiment of the present disclosure.

FIG. 7 is a block diagram illustrating a representation of an example of a configuration of an electronic system employing at least one of the semiconductor devices and the semiconductor systems illustrated in FIG. 1 to FIG. 6.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

Various embodiments may be directed to semiconductor devices correcting errors of read data and semiconductor systems including the same.

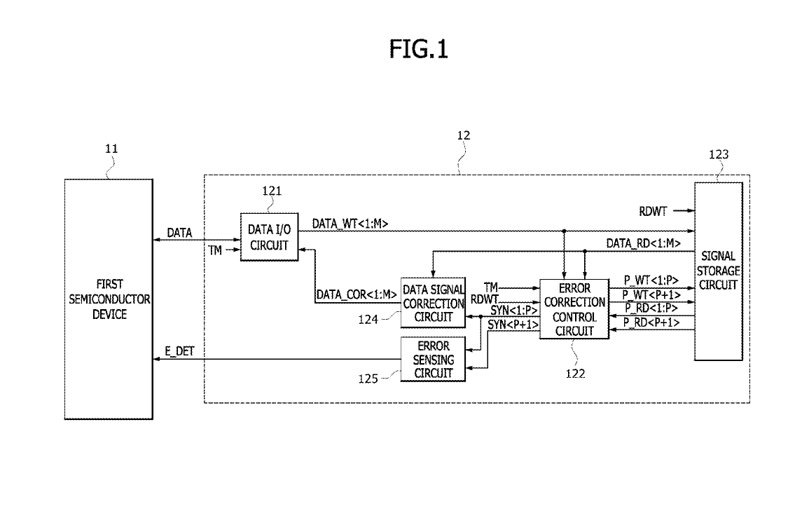

Referring to FIG. 1, a semiconductor system according to an embodiment of the present disclosure may include a first semiconductor device 11 and a second semiconductor device 12.

The first semiconductor device 11 may receive and output a data signal DATA, and may receive an error sensing signal E_DET.

The second semiconductor device 12 may include a data input and output (I/O) circuit 121, an error correction control circuit 122, a signal storage circuit 123, a data signal correction circuit 124, and an error sensing circuit 125.

The data I/O circuit 121 may output the data signal DATA as first to M^{th} write data signals DATA_WT<1:M> or may receive first to M^{th} correction data signals DATA_COR<1:M> to output first to M^{th} correction data signals DATA_COR<1:M> as the data signal DATA, in response to a test mode signal TM. In the first to M^{th} write data signals DATA_WT<1:M> and the first to M^{th} correction data signals DATA_COR<1:M>, “M” may be set to a natural number. The test mode signal TM may be a signal which is enabled to have a logic high level in a test mode. The test mode signal TM may be provided by an external device or may be generated in the second semiconductor device 12. The data I/O circuit 121 may receive the data signal DATA to output the data signal DATA as the first to M^{th} write data signals DATA_WT<1:M> in response to the test mode signal TM, if a write operation is performed while the data I/O circuit 121 is operating in a normal mode. The data I/O circuit 121 may receive the first to M^{th} correction data signals DATA_COR<1:M> to output the first to M^{th} correction data signals DATA_COR<1:M> as the data signal DATA in response to the test mode signal TM, if a read operation is performed while the data I/O circuit 121 is operating in the normal mode. The data I/O circuit 121 may receive the data signal DATA to output the data signal DATA as the first to (M−1)^{th} write data signals DATA_WT<1:M−1> in response to the test mode signal TM, if the write operation is performed while the data I/O circuit 121 is operating in a test mode. The data I/O circuit 121 may not generate the M^{th} write data signal DATA_WT<M>, if the write operation is performed while the data I/O circuit 121 is operating in the test mode.

The error correction control circuit 122 may receive the first to M^{th} write data signals DATA_WT<1:M> to generate first to (P+1)^{th} write parity signals P_WT<1:P+1> or may receive first to M^{th} read data signals DATA_RD<1:M> and first to (P+1)^{th} read parity signals P_RD<1:P+1> to generate first to (P+1)^{th} syndrome signals SYN<1:P+1>, in response to the test mode signal TM and a read/write signal RDWT. In the first to (P+1)^{th} write parity signals P_WT<1:P+1> and the first to M^{th} read data signals DATA_RD<1:M>, “P” may be set to a natural number. The read/write signal RDWT may be set to have a logic low level if the read operation is performed and may be set to have a logic high level if the write operation is performed. Logic levels of the read/write signal RDWT may be set to be different according to the embodiments. The read/write signal RDWT may generated by decoding a command signal (not illustrated) which may be provided by an external device. The error correction control circuit 122 may generate the first to P^{th} write parity signals P_WT<1:P> and the first to P^{th} syndrome signals SYN<1:P> which are used for single error correction (SEC) while the error correction control circuit 122 is operating in a normal mode and may generate the first to (P+1)^{th} write parity signals P_WT<1:P+1> and the first to (P+1)^{th} syndrome signals SYN<1:P+1> which are used for single error correction-double error detection (SEC-DED) while the error correction control circuit 122 is operating in a test mode, in response to the test mode signal TM and the read/write signal RDWT.

The error correction control circuit 122 may receive the first to M^{th} write data signals DATA_WT<1:M> to generate the first to P^{th} write parity signals P_WT<1:P> in response to the test mode signal TM and the read/write signal RDWT, if the write operation is performed in the normal mode. The number “P” in the first to P^{th} write parity signals P_WT<1:P> may be set such that the single error correction of the first to M^{th} write data signals DATA_WT<1:M> and the first to P^{th} write parity signals P_WT<1:P> is performed using hamming codes. Each of the first to P^{th} write parity signals P_WT<1:P> may be generated by performing a logical operation of at least two write data signals among the first to M^{th} write data signals DATA_WT<1:M>. The number of the write data signals used in the logical operation for generating each of the first to P^{th} write parity signals P_WT<1:P> may be two or more. The logical operation may be an exclusive OR operation. For example, if the number “P” is set to be three and the number “M” is set to be four, the error correction control circuit 122 may operate as follows. If the write operation is performed in the normal mode, the error correction control circuit 122 may perform an exclusive OR operation of the second write data signal DATA_WT<2>, the third write data signal DATA_WT<3> and the fourth write data signal DATA_WT<4> to generate the first write parity signal P_WT<1>, may perform an exclusive OR operation of the first write data signal DATA_WT<1>, the third write data signal DATA_WT<3> and the fourth write data signal DATA_WT<4> to generate the second write parity signal P_WT<2>, and may perform an exclusive OR operation of the first write data signal DATA_WT<1>, the second write data signal DATA_WT<2> and the fourth write data signal DATA_WT<4> to generate the third write parity signal P_WT<3>, in response to the test mode signal TM and the read/write signal RDWT. As described above, the first to third write parity signals P_WT<1:3> may be generated by performing exclusive OR operations of three different combinations including at least two signals among the first to fourth write data signals DATA_WT<1:4>, respectively. The first write data signal DATA_WT<1> may be used in the logical operations for generating the second write parity signal P_WT<2> and the third write parity signal P_WT<3>, the second write data signal DATA_WT<2> may be used in the logical operations for generating the first write parity signal P_WT<1> and the third write parity signal P_WT<3>, the third write data signal DATA_WT<3> may be used in the logical operations for generating the second write parity signal P_WT<2> and the third write parity signal P_WT<3>, and the fourth write data signal DATA_WT<4> may be used in the logical operations for generating the first to third write parity signals P_WT<1:3>. Hence, the number of the write data signals used in the logical operation for generating each of the first to third write parity signals P_WT<1:3> may be two or more.

If the read operation is performed in the normal mode, the error correction control circuit 122 may receive the first to M^{th} read data signals DATA_RD<1:M> and the first to P^{th} read parity signals P_RD<1:P> to generate the first to P^{th} syndrome signals SYN<1:P>, in response to the test mode signal TM and the read/write signal RDWT. Each of the first to P^{th} syndrome signals SYN<1:P> may be generated by performing a logical operation of at least two write data signals among the first to M^{th} write data signals DATA_WT<1:M> and any one read parity signal among the first to P^{th} read parity signals P_RD<1:P>. The number of the read data signals used in the logical operation for generating each of the first to P^{th} syndrome signals SYN<1:P> may be two or more. For example, if the number “P” is set to be 3 and the number “M” is set to be 4, the error correction control circuit 122 may operate as follows. If the read operation is performed in the normal mode, the error correction control circuit 122 may perform an exclusive OR operation of the second read data signal DATA_RD<2>, the third read data signal DATA_RD<3>, the fourth read data signal DATA_RD<4> and the first read parity signal P_RD<1> to generate the first syndrome signal SYN<1>, may perform an exclusive OR operation of the first read data signal DATA_RD<1>, the third read data signal DATA_RD<3>, the fourth read data signal DATA_RD<4> and the second read parity signal P_RD<2> to generate the second syndrome signal SYN<2>, and may perform an exclusive OR operation of the first read data signal DATA_RD<1>, the second read data signal DATA_RD<2>, the fourth read data signal DATA_RD<4> and the third read parity signal P_RD<3> to generate the third syndrome signal SYN<3>, in response to the test mode signal TM and the read/write signal RDWT. The first read data signal DATA_RD<1> may be used in the logical operations for generating the second syndrome signal SYN<2> and the third syndrome signal SYN<3>, the second read data signal DATA_RD<2> may be used in the logical operations for generating the first syndrome signal SYN<1> and the third syndrome signal SYN<3>, the third read data signal DATA_RD<3> may be used in the logical operations for generating the first syndrome signal SYN<1> and the second syndrome signal SYN<2>, and the fourth read data signal DATA_RD<4> may be used in the logical operations for generating the first to third syndrome signals SYN<1:3>. Hence, the number of the write data signals used in the logical operation for generating each of the first to third syndrome signals SYN<1:3> may be at least two.

If the read operation is performed in the normal mode, the error correction control circuit 122 according to the present embodiment may generate the first to P^{th} syndrome signals SYN<1:P> from the first to M^{th} read data signals DATA_RD<1:M> and the first to P^{th} read parity signals P_RD<1:P>. If no errors are in the first to M^{th} read data signals DATA_RD<1:M>, all of the first to P^{th} syndrome signals SYN<1:P> may have a logic low level corresponding to a level “0”. The first to P^{th} syndrome signals SYN<1:P> may have a logic level combination corresponding to a read data signal having an error. For example, if the number “P” is set to 3 and the number “M” is set to 4, the error correction control circuit 122 may operate as follows. If the first read data signal DATA_RD<1> has an error, the first to third syndrome signals SYN<1:3> may have a logic level combination of (0,1,1). If the second read data signal DATA_RD<2> has an error, the first to third syndrome signals SYN<1:3> may have a logic level combination of (1,0,1). If the third read data signal DATA_RD<3> has an error, the first to third syndrome signals SYN<1:3> may have a logic level combination of (1,1,0). If the fourth read data signal DATA_RD<4> has an error, the first to third syndrome signals SYN<1:3> may have a logic level combination of (1,1,1). In the first to third syndrome signals SYN<1:3>, the logic level combination of (0,1,1) means that the first syndrome signal SYN<1> has a logic low level of “0” and the second and third syndrome signals SYN<2:3> have a logic high level of “1”. The logic level combination of (1,0,1) in the first to third syndrome signals SYN<1:3> means that the first and third syndrome signals SYN<1> and SYN<3> have a logic high level of “1” and the second syndrome signal SYN<2> has a logic low level of “0”.

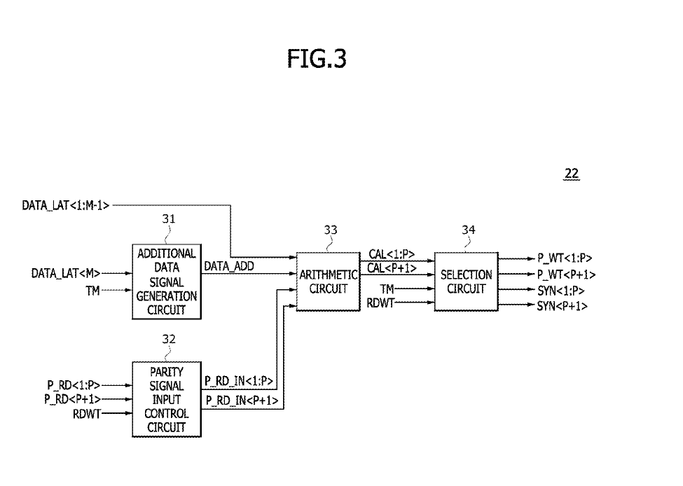

If the write operation is performed in the test mode, the error correction control circuit 122 may receive the first to (M−1)^{th} write data signals DATA_WT<1:M−1> to generate the first to (P+1)^{th} write parity signals P_WT<1:P+1>, in response to the test mode signal TM and the read/write signal RDWT. The error correction control circuit 122 may perform a single error correction-double error detection (SEC-DED) operation of the first to (M−1)^{th} write data signals DATA_WT<1:M−1> and the first to (P+1)^{th} write parity signals P_WT<1:P+1> by additionally generating the (P+1)^{th} write parity signal in the test mode, as compared with the normal mode. The error correction control circuit 122 may use an additional data signal (DATA_ADD of FIG. 3), which is fixed to a logic high level, as the M^{th} writ data signal DATA_WT<M> in the test mode. Each of the first to (P+1)^{th} write parity signals P_WT<1:P+1> may be generated by performing a logical operation of at least two data signals among the first to (M−1)^{th} write data signals DATA_WT<1:M−1> and the additional data signal (DATA_ADD of FIG. 3). The total number of the write data signals and the additional data signal (DATA_ADD of FIG. 3) used in the logical operation for generating each of the first to (P+1)^{th} write parity signals P_WT<1:P+1> may be set to be an odd number. For example, if the number “P” is set to 3 and the number “M” is set to 4, the error correction control circuit 122 may operate as follows. If the write operation is performed in the test mode, the error correction control circuit 122 may perform an exclusive OR operation of the second write data signal DATA_WT<2>, the third write data signal DATA_WT<3> and the additional data signal (DATA_ADD of FIG. 3) to generate the first write parity signal P_WT<1>, may perform an exclusive OR operation of the first write data signal DATA_WT<1>, the third write data signal DATA_WT<3> and the additional data signal (DATA_ADD of FIG. 3) to generate the second write parity signal P_WT<2>, may perform an exclusive OR operation of the first write data signal DATA_WT<1>, the second write data signal DATA_WT<2> and the additional data signal (DATA_ADD of FIG. 3) to generate the third write parity signal P_WT<3>, and may perform an exclusive OR operation of the first write data signal DATA_WT<1>, the second write data signal DATA_WT<2> and the third write data signal DATA_WT<3> to generate the fourth write parity signal P_WT<4>, in response to the test mode signal TM and the read/write signal RDWT. As such, each of the first to fourth write parity signals P_WT<1:4> may be generated by performing a logical operation of at least two write data signals. Moreover, the first write data signal DATA_WT<1> may be used in the logical operations for generating the second to fourth write parity signals P_WT<2:4>, the second write data signal DATA_WT<2> may be used in the logical operations for generating the first write parity signal P_WT<1>, the third write parity signal P_WT<3> and the fourth write parity signal P_WT<4>, the third write data signal DATA_WT<3> may be used in the logical operations for generating the first write parity signal P_WT<1>, the second write parity signal P_WT<2> and the fourth write parity signal P_WT<4>, and the fourth write data signal DATA_WT<4> may be used in the logical operations for generating the first to third write parity signals P_WT<1:3>. Hence, the total number of the data signals used in the logical operation for generating each of the first to fourth write parity signals P_WT<1:4> may be set to an odd number.

If the read operation is performed in the test mode, the error correction control circuit 122 may receive the first to (M−1)^{th} read data signals DATA_RD<1:M−1> and the first to (P+1)^{th} read parity signals P_RD<1:P+1> to generate the first to (P+1)^{th} syndrome signals SYN<1:P+1>, in response to the test mode signal TM and the read/write signal RDWT. The error correction control circuit 122 may use the additional data signal (DATA_ADD of FIG. 3) fixed to a logic high level as the M^{th} write data signal DATA_WT<M> in the test mode. Each of the first to (P+1)^{th} syndrome signals SYN<1:P+1> may be generated by performing a logical operation of at least two data signals of the first to (M−1)^{th} read data signals DATA_RD<1:M−1> and the additional data signal (DATA_ADD of FIG. 3) and any one read parity signal of the first to (P+1)^{th} read parity signals P_RD<1:P+1>. The number of the data signals used in the logical operation for generating each of the first to (P+1)^{th} syndrome signals SYN<1:P+1> may be set to an odd number. For example, if the number “P” is set to 3 and the number “M” is set to 4, the error correction control circuit 122 may operate as follows. If the read operation is performed in the test mode, the error correction control circuit 122 may perform an exclusive OR operation of the second read data signal DATA_RD<2>, the third read data signal DATA_RD<3>, the additional data signal (DATA_ADD of FIG. 3) and the first read parity signal P_RD<1> to generate the first syndrome signal SYN<1>, may perform an exclusive OR operation of the first read data signal DATA_RD<1>, the third read data signal DATA_RD<3>, the additional data signal (DATA_ADD of FIG. 3) and the second read parity signal P_RD<2> to generate the second syndrome signal SYN<2>, may perform an exclusive OR operation of the first read data signal DATA_RD<1>, the second read data signal DATA_RD<2>, the additional data signal (DATA_ADD of FIG. 3) and the third read parity signal P_RD<3> to generate the third syndrome signal SYN<3>, and may perform an exclusive OR operation of the first read data signal DATA_RD<1>, the second read data signal DATA_RD<2>, the third read data signal DATA_RD<3> and the fourth read parity signal P_RD<4> to generate the fourth syndrome signal SYN<4>, in response to the test mode signal TM and the read/write signal RDWT. In addition, the first read data signal DATA_RD<1> may be used in the logical operations for generating the second to fourth syndrome signals SYN<2:4>, the second read data signal DATA_RD<2> may be used in the logical operations for generating the first syndrome signal SYN<1>, the third syndrome signal SYN<3> and the fourth syndrome signal SYN<4>, the third read data signal DATA_RD<3> may be used in the logical operations for generating the first syndrome signal SYN<1>, the second syndrome signal SYN<2> and the fourth syndrome signal SYN<4>, and the additional data signal (DATA_ADD of FIG. 3) may be used in the logical operations for generating the first to third syndrome signals SYN<1:3>. Hence, the total number of the read data signals and the additional data signal (DATA_ADD of FIG. 3) which are used in the logical operation for generating each of the first to fourth syndrome signals SYN<1:4> may be set to an odd number.

As described above, if the read operation is performed in the test mode, the error correction control circuit 122 according to a present embodiment may generate the first to (P+1)^{th} syndrome signals SYN<1:P+1> from the first to (M−1)^{th} read data signals DATA_RD<1:M−1>, the additional data signal, and the first to (P+1)^{th} read parity signals P_RD<1:P+1>. If no errors are in the first to (M−1)^{th} read data signals DATA_RD<1:M−1> and the first to (P+1)^{th} read parity signals P_RD<1:P+1>, the first to (P+1)^{th} syndrome signals SYN<1:P+1> may have a logic low level of “0”. If the first to (M−1)^{th} read data signals DATA_RD<1:M−1> and the first to (P+1)^{th} read parity signals P_RD<1:P+1> have an erroneous bit, the first to (P+1)^{th} syndrome signals SYN<1:P+1> may have a logic level combination including “1”. For example, if one of the bits included in the first to (M−1)^{th} data read data signals DATA_RD<1:M−1> and the first to (P+1)^{th} read parity signals P_RD<1:P+1> is an erroneous bit, the number of logic high leveled bits of the first to (P+1)^{th} syndrome signals SYN<1:P+1> may be an odd number. If two of the bits included in the first to (M−1)^{th} data read data signals DATA_RD<1:M−1> and the first to (P+1)^{th} read parity signals P_RD<1:P+1> are erroneous bits, the number of logic high leveled bits of the first to (P+1)^{th} syndrome signals SYN<1:P+1> may be an even number. In contrast, in some embodiments, the number of logic high leveled bits of the first to (P+1)^{th} syndrome signals SYN<1:P+1> may be an even number if one of the bits included in the first to (M−1)^{th} data read data signals DATA_RD<1:M−1> and the first to (P+1)^{th} read parity signals P_RD<1:P+1> is an erroneous bit, and the number of logic high leveled bits of the first to (P+1)^{th} syndrome signals SYN<1:P+1> may be an odd number if two of the bits included in the first to (M−1)^{th} data read data signals DATA_RD<1:M−1> and the first to (P+1)^{th} read parity signals P_RD<1:P+1> are erroneous bits.

The signal storage circuit 123 may store the first to M^{th} write data signals DATA_WT<1:M> and the first to (P+1)^{th} write parity signals P_WT<1:P+1> therein and may output the first to M^{th} read data signals DATA_RD<1:M> and the first to (P+1)^{th} read parity signals P_RD<1:P+1>, in response to the read/write signal RDWT. The signal storage circuit 123 may include a first storage region (not illustrated) in which the data signals are stored and a second storage region (not illustrated) in which the parity signals are stored. If the first to M^{th} write data signals DATA_WT<1:M> and the first to P^{th} write parity signals P_WT<1:P> are inputted to the signal storage circuit 123 while the second semiconductor device 12 is operating in the normal mode, the signal storage circuit 123 may store the first to M^{th} write data signals DATA_WT<1:M> in the first storage region (not illustrated) thereof and may store the first to P^{th} write parity signals P_WT<1:P> in the second storage region (not illustrated) thereof. If the first to (M−1)^{th} write data signals DATA_WT<1:M−1> and the first to (P+1)^{th} write parity signals P_WT<1:P+1> are inputted to the signal storage circuit 123 while the second semiconductor device 12 is operating in the test mode, the signal storage circuit 123 may store the first to (M−1)^{th} write data signals DATA_WT<1:M−1> and the (P+1)^{th} write parity signal P_WT<P+1> in the first storage region (not illustrated) and may store the first to P^{th} write parity signals P_WT<1:P> in the second storage region (not illustrated). The M^{th} write data signal DATA_WT<M> inputted while the second semiconductor device 12 is operating in the normal mode and the (P+1)^{th} write parity signal P_WT<P+1> inputted while the second semiconductor device 12 is operating in the test mode may be inputted through the same transmission line. The signal storage circuit 123 may output the first to M^{th} read data signals DATA_RD<1:M> stored in the first storage region (not illustrated) and the first to P^{th} read parity signals P_RD<1:P> stored in the second storage region (not illustrated), while the second semiconductor device 12 is operating in the normal mode. The signal storage circuit 123 may output the first to (M−1)^{th} read data signals DATA_RD<1:M−1> and the (P+1)^{th} read parity signal P_RD<P+1> stored in the first storage region (not illustrated) and the first to P^{th} read parity signals P_RD<1:P> stored in the second storage region (not illustrated), while the second semiconductor device 12 is operating in the test mode. The M^{th} read data signal DATA_RD<M> outputted while the second semiconductor device 12 is operating in the normal mode and the (P+1)^{th} read parity signal P_RD<P+1> outputted while the second semiconductor device 12 is operating in the test mode may be outputted through the same transmission line.

The data signal correction circuit 124 may correct an error of the first to M^{th} read data signals DATA_RD<1:M> to output the corrected signals as the first to M^{th} correction data signals DATA_COR<1:M>, in response to the first to P^{th} syndrome signals SYN<1:P>. If the read operation is performed in the normal mode, the data signal correction circuit 124 may correct an error of any one bit included in the first to M^{th} read data signals DATA_RD<1:M> according to a logic level combination of the first to P^{th} syndrome signals SYN<1:P> to output the corrected signals as the first to M^{th} correction data signals DATA_COR<1:M>.

The error sensing circuit 125 may receive the first to (P+1)^{th} syndrome signals SYN<1:P+1> to generate the error sensing signal E_DET. In the test mode, if the number of “1” indicating a logic high level among the first to (P+1)^{th} syndrome signals SYN<1:P+1> is an even number, the error sensing circuit 125 may consider two of the bits included in the first to (M−1)^{th} read data signals DATA_RD<1:M−1> and the first to (P+1)^{th} read parity signals P_RD<1:P+1> to be erroneous bits and may generate the error sensing signal E_DET. In some embodiment, if one of the bits included in the first to (M−1)^{th} read data signals DATA_RD<1:M−1> and the first to (P+1)^{th} read parity signals P_RD<1:P+1> is an erroneous bit, the error sensing circuit 125 may generate the error sensing signal E_DET according to a logic level combination of the first to (P+1)^{th} syndrome signals SYN<1:P+1>. If at least one of the bits included in the first to (M−1)^{th} read data signals DATA_RD<1:M−1> and the first to (P+1)^{th} read parity signals P_RD<1:P+1> has an error, the error sensing circuit 125 may store information on locations where the first to (M−1)^{th} read data signals DATA_RD<1:M−1> and the first to (P+1)^{th} read parity signals P_RD<1:P+1> are stored according to the first to (P+1)^{th} syndrome signals SYN<1:P+1>.

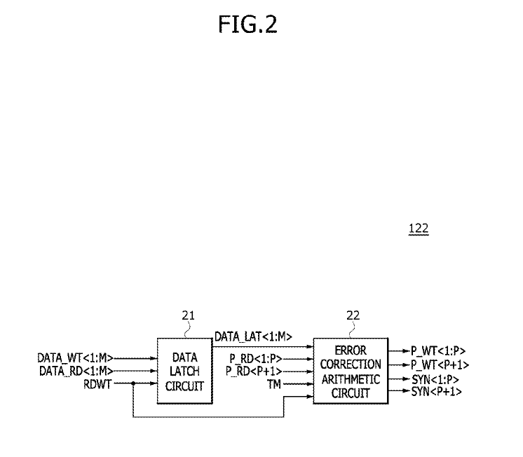

Referring to FIG. 2, the error correction control circuit 122 may include a data latch circuit 21 and an error correction arithmetic circuit 22.

The data latch circuit 21 may latch the first to M^{th} write data signals DATA_WT<1:M> or the first to M^{th} read data signals DATA_RD<1:M> to output the latched signals as first to M^{th} latch data signals DATA_LAT<1:M>, in response to the read/write signal RDWT. If the write operation is performed, the data latch circuit 21 may latch the first to M^{th} write data signals DATA_WT<1:M> to output the latched write data signals as the first to M^{th} latch data signals DATA_LAT<1:M> in response to the read/write signal RDWT. If the read operation is performed, the data latch circuit 21 may latch the first to M^{th} read data signals DATA_RD<1:M> to output the latched read data signals as the first to M^{th} latch data signals DATA_LAT<1:M> in response to the read/write signal RDWT.

The error correction arithmetic circuit 22 may receive the first to M^{th} latch data signals DATA_LAT<1:M> and the first to (P+1)^{th} read parity signals P_RD<1:P+1> to generate the first to (P+1)^{th} write parity signals P_WT<1:P+1> or the first to (P+1)^{th} syndrome signals SYN<1:P+1>, in response to the test mode signal TM and the read/write signal RDWT. If the write operation is performed in the normal mode, the error correction arithmetic circuit 22 may perform a predetermined logic operation on the first to M^{th} latch data signals DATA_LAT<1:M> to generate the first to P^{th} write parity signals P_WT<1:P>, in response to the test mode signal TM and the read/write signal RDWT. If the read operation is performed in the normal mode, the error correction arithmetic circuit 22 may perform a predetermined logic operation on the first to M^{th} latch data signals DATA_LAT<1:M> and the first to P^{th} read parity signals P_RD<1:P> to generate the first to P^{th} syndrome signals SYN<1:P>, in response to the test mode signal TM and the read/write signal RDWT. If the write operation is performed in the test mode, the error correction arithmetic circuit 22 may perform a predetermined logic operation on the first to (M−1)^{th} latch data signals DATA_LAT<1:M−1> to generate the first to (P+1)^{th} write parity signals P_WT<1:P+1>, in response to the test mode signal TM and the read/write signal RDWT. If the read operation is performed in the test mode, the error correction arithmetic circuit 22 may perform a predetermined logic operation on the first to (M−1)^{th} latch data signals DATA_LAT<1:M−1> and the first to (P+1)^{th} read parity signals P_RD<1:P+1> to generate the first to (P+1)^{th} syndrome signals SYN<1:P+1>, in response to the test mode signal TM and the read/write signal RDWT.

Referring to FIG. 3, the error correction arithmetic circuit 22 may include an additional data signal generation circuit 31, a parity signal input control circuit 32, an arithmetic circuit 33, and a selection circuit 34.

The additional data signal generation circuit 31 may receive the M^{th} latch data signal DATA_LAT<M> to generate an additional data signal DATA_ADD in response to the test mode signal TM. The additional data signal generation circuit 31 may buffer the M^{th} latch data signal DATA_LAT<M> to generate the additional data signal DATA_ADD in response to the test mode signal TM in the normal mode. The additional data signal generation circuit 31 may generate the additional data signal DATA_ADD, which is set to a logic high level, in response to the test mode signal TM in the test mode. Logic levels of the additional data signal DATA_ADD in the test mode may be set to be different according to the embodiments.

The parity signal input control circuit 32 may receive the first to (P+1)^{th} read parity signals P_RD<1:P+1> to generate first to (P+1)^{th} read input parity signals P_RD_IN<1:P+1> in response to the read/write signal RDWT. If the write operation is performed, the parity signal input control circuit 32 may generate the first to (P+1)^{th} read input parity signals P_RD_IN<1:P+1>, which are set to a logic low level, in response to the read/write signal RDWT. If the read operation is performed, the parity signal input control circuit 32 may buffer the first to (P+1)^{th} read parity signals P_RD<1:P+1> to generate the first to (P+1)^{th} read input parity signals P_RD_IN<1:P+1> in response to the read/write signal RDWT.

The arithmetic circuit 33 may receive the first to (M−1)^{th} latch data signals DATA_LAT<1:M−1>, the additional data signal DATA_ADD and the first to fourth read input parity signals P_RD_IN<1:4> and may perform a logic operation thereon to generate first to (P+1)^{th} arithmetic signals CAL<1:P+1>. The arithmetic circuit 33 may perform an exclusive OR operation on at least two data signals of the first to (M−1)^{th} latch data signals DATA_LAT<1:M−1> and the additional data signal DATA_ADD and one signal of the first to (P+1)^{th} read input parity signals P_RD_IN<1:P+1> to generate any one of the first to (P+1)^{th} arithmetic signals CAL<1:P+1>. The total number of the latch data signals and the additional data signal DATA_ADD used in the logical operation for generating each of the first to (P+1)^{th} arithmetic signals CAL<1:P+1> may be an odd number.

The selection circuit 34 may output the first to (P+1)^{th} arithmetic signals CAL<1:P+1> as the first to (P+1)^{th} write parity signals P_WT<1:P+1> or the first to (P+1)^{th} syndrome signals SYN<1:P+1> in response to the test mode signal TM and the read/write signal RDWT. If the write operation is performed in the normal mode, the selection circuit 34 may output the first to P^{th} arithmetic signals CAL<1:P> as the first to P^{th} write parity signals P_WT<1:P> in response to the test mode signal TM and the read/write signal RDWT. If the read operation is performed in the normal mode, the selection circuit 34 may output the first to P^{th} arithmetic signals CAL<1:P> as the first to P^{th} syndrome signals SYN<1:P> in response to the test mode signal TM and the read/write signal RDWT. If the write operation is performed in the test mode, the selection circuit 34 may output the first to (P+1)^{th} arithmetic signals CAL<1:P+1> as the first to (P+1)^{th} write parity signals P_WT<1:P+1> in response to the test mode signal TM and the read/write signal RDWT. If the read operation is performed in the test mode, the selection circuit 34 may output the first to (P+1)^{th} arithmetic signals CAL<1:P+1> as the first to (P+1)^{th} syndrome signals SYN<1:P+1> in response to the test mode signal TM and the read/write signal RDWT.

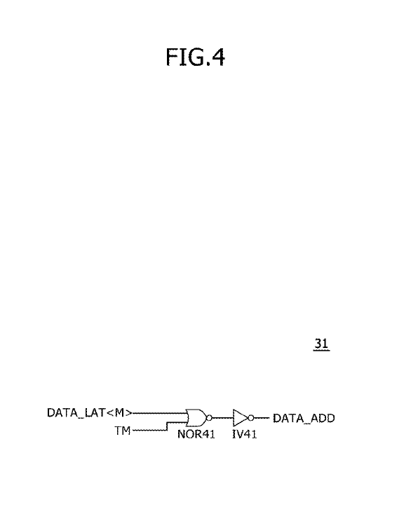

Referring to FIG. 4, the additional data signal generation circuit 31 may include logic gates, for example, a NOR gate NOR41 and an inverter IV41. The NOR gate NOR41 may receive the M^{th} latch data signal DATA_LAT<M> and the test mode signal TM and may perform a NOR operation thereon to output the NOR operation result. The inverter IV41 may inversely buffer an output signal of the NOR gate NOR41 to output the inversely buffered signal as the additional data signal DATA_ADD. Thus, if the test mode signal TM has a logic low level in the normal mode, the additional data signal generation circuit 31 may buffer the M^{th} latch data signal DATA_LAT<M> to output the buffered signal as the additional data signal DATA_ADD. If the test mode signal TM has a logic high level in the test mode, the additional data signal generation circuit 31 may generate the additional data signal DATA_ADD having a logic high level.

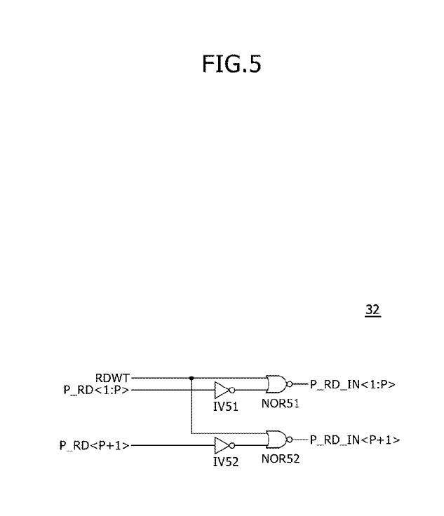

Referring to FIG. 5, the parity signal input control circuit 32 may include logic gates, for example, inverters IV51 and IV52, and NOR gates NOR51 and NOR52. The inverter IV51 may inversely buffer the first to P^{th} read parity signals P_RD<1:P> to output the inversely buffered signals. The NOR gate NOR51 may receive the read/write signal RDWT and an output signal of the inverter IV51 and may perform a NOR operation thereon to output the NOR operation result as the first to P^{th} read input parity signals P_RD_IN<1:P>. In an embodiment, FIG. 5 illustrates an example in which the number of the inverter IV51 is one and the number of the NOR gate NOR51 is one. However, the parity signal input control circuit 32 may be actually configured to include a plurality of inverters IV51 and a plurality of NOR gates NOR51 or logic gates. In such a case, the number of the inverters IV51 and the number of the NOR gates NOR51 may be equal to the number “P” in the first to P^{th} read parity signals P_RD<1:P>. The inverter IV52 may inversely buffer the (P+1)^{th} read parity signal P_RD<P+1> to output the inverted (P+1)^{th} read parity signal P_RD<P+1>. The NOR gate NOR52 may receive the read/write signal RDWT and an output signal of the inverter IV52 and may perform a NOR operation thereon to output the NOR operation result as the (P+1)^{th} read input parity signal P_RD_IN<P+1>. Thus, if the read/write signal RDWT has a logic high level during the write operation, the parity signal input control circuit 32 may output the first to (P+1)^{th} read input parity signals P_RD_IN<1:P+1> having a logic low level. If the read/write signal RDWT has a logic low level during the read operation, the parity signal input control circuit 32 may buffer the first to (P+1)^{th} read parity signals P_RD<1:P+1> to output the buffered signals as the first to (P+1)^{th} read input parity signals P_RD_IN<1:P+1>.

As described above, the semiconductor system according to an embodiment may receive the first to M^{th} write data signals DATA_WT<1:M> to generate the first to P^{th} write parity signals P_WT<1:P> and may store the first to P^{th} write parity signals P_WT<1:P> therein if the write operation is performed in the normal mode, and the semiconductor system may generate the first to P^{th} syndrome signals SYN<1:P> from the first to M^{th} read data signals DATA_RD<1:M> and the first to P^{th} read parity signals P_RD<1:P> and may correct one bit error occurred in the first to M^{th} read data signals DATA_RD<1:M> to output the corrected signals according to the first to P^{th} syndrome signals SYN<1:P> if the read operation is performed in the normal mode. However, since the first to P^{th} syndrome signals SYN<1:P> have a limitation on the number of logic level combinations, the first to P^{th} syndrome signals SYN<1:P> may not include information on two erroneous bits of the first to M^{th} read data signals DATA_RD<1:M>. Thus, if the write operation is performed in the test mode, the semiconductor system may receive the first to (M−1)^{th} write data signals DATA_WT<1:M−1> to generate the first to (P+1)^{th} write parity signals P_WT<1:P+1> and may store the first to (P+1)^{th} write parity signals P_WT<1:P+1> therein. In addition, the semiconductor system may generate the first to (P+1)^{th} syndrome signals SYN<1:P+1> from the first to (M−1)^{th} read data signals DATA_RD<1:M−1> and the first to (P+1)^{th} read parity signals P_RD<1:P+1>. Accordingly, the semiconductor system may sense even an error of two bits among the bits included in the first to (M−1)^{th} read data signals DATA_RD<1:M−1> and the first to (P+1)^{th} read parity signals P_RD<1:P+1>. Moreover, since the (P+1)^{th} write parity signal P_WT<P+1> added in the test mode is stored in the same storage region where the M^{th} write data signal DATA_WT<M> is stored, no additional storage region is required. Accordingly, an area of the semiconductor system may be reduced.

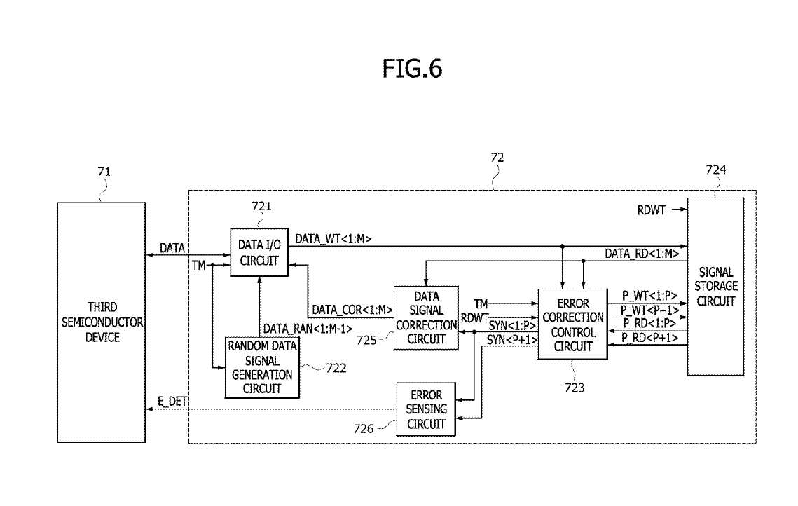

Referring to FIG. 6, a semiconductor system according to an embodiment of the present disclosure may include a third semiconductor device 71 and a fourth semiconductor device 72.

The third semiconductor device 71 may receive and output a data signal DATA, and may receive an error sensing signal E_DET.

The fourth semiconductor device 72 may include a data I/O circuit 721, a random data signal generation circuit 722, an error correction control circuit 723, a signal storage circuit 724, a data signal correction circuit 725, and an error sensing circuit 726.

The data I/O circuit 721 may output the data signal DATA as first to M^{th} write data signals DATA_WT<1:M> or may output first to M^{th} correction data signals DATA_COR<1:M> as the data signal DATA, in response to a test mode signal TM. The test mode signal TM may be enabled to have a logic high level in a test mode. The test mode signal TM may be provided by an external device or may be generated in the fourth semiconductor device 72. The data I/O circuit 721 may receive the data signal DATA to output the data signal DATA as the first to M^{th} write data signals DATA_WT<1:M> in response to the test mode signal TM, if a write operation is performed while the data I/O circuit 721 is operating in a normal mode. The data I/O circuit 721 may receive the first to M^{th} correction data signals DATA_COR<1:M> to output the first to M^{th} correction data signals DATA_COR<1:M> as the data signal DATA in response to the test mode signal TM, if a read operation is performed while the data I/O circuit 721 is operating in the normal mode. The data I/O circuit 721 may receive first to (M−1)^{th} random data signals DATA_RAN<1:M−1> to output the first to (M−1)^{th} random data signals DATA_RAN<1:M−1> as the first to (M−1)^{th} write data signals DATA_WT<1:M−1> in response to the test mode signal TM, if the write operation while the data I/O circuit 721 is operating is performed in a test mode. The data I/O circuit 721 may not generate the M^{th} write data signal DATA_WT<M>, if the write operation is performed while the data I/O circuit 721 is operating in the test mode.

If the number “M” in the first to (M−1)^{th} random data signals DATA_RAN<1:M−1> is four, the random data signal generation circuit 722 may generate the first to third random data signals DATA_RAN<1:3> in response to the test mode signal TM. If the random data signal generation circuit 722 enters the test mode, the random data signal generation circuit 722 may generate the first to third random data signals DATA_RAN<1:3> having an arbitrary logic level combination in response to the test mode signal TM.

The error correction control circuit 723 may receive the first to fourth write data signals DATA_WT<1:4> to generate first to fourth write parity signals P_WT<1:4> or may receive first to fourth read data signals DATA_RD<1:4> and first to fourth read parity signals P_RD<1:4> to generate first to fourth syndrome signals SYN<1:4>, in response to the test mode signal TM and a read/write signal RDWT. The error correction control circuit 723 may have the same configuration as the error correction control circuit 122 described with reference to FIGS. 1 to 5. Thus, a description of the error correction control circuit 723 will be omitted hereinafter.

The signal storage circuit 724 may store the first to M^{th} write data signals DATA_WT<1:M> and the first to (P+1)^{th} write parity signals P_WT<1:P+1> therein or may output the first to M^{th} read data signals DATA_RD<1:M> and the first to (P+1)^{th} read parity signals P_RD<1:P+1> stored therein, in response to the read/write signal RDWT. The signal storage circuit 724 may have the same configuration as the signal storage circuit 123 described with reference to FIG. 1. Thus, a description of the signal storage circuit 724 will be omitted hereinafter.

The data signal correction circuit 725 may correct an error of the first to M^{th} read data signals DATA_RD<1:M> to output the corrected signals as the first to M^{th} correction data signals DATA_COR<1:M>, in response to the first to P^{th} syndrome signals SYN<1:P>. If the read operation is performed in the normal mode, the data signal correction circuit 725 may correct an error of one bit among the bits included in the first to M^{th} read data signals DATA_RD<1:M> according to a logic level combination of the first to P^{th} syndrome signals SYN<1:P> to output the corrected signals as the first to M^{th} correction data signals DATA_COR<1:M>. The read/write signal RDWT may be set to have a logic low level if the read operation is performed and may be set to have a logic high level if the write operation is performed. The logic levels of the read/write signal RDWT may be set to be different according to the embodiments. The read/write signal RDWT may be generated by decoding a command signal (not illustrated) which is provided by an external device.

The error sensing circuit 726 may receive the first to (P+1)^{th} syndrome signals SYN<1:P+1> to generate the error sensing signal E_DET. In the test mode, if the number of “1” indicating a logic high level among the logic levels of the first to (P+1)^{th} syndrome signals SYN<1:P+1> is an even number, the error sensing circuit 726 may consider two of the bits included in the first to (M−1)^{th} read data signals DATA_RD<1:M−1> and the first to (P+1)^{th} read parity signals P_RD<1:P+1> to be erroneous bits and may generate the error sensing signal E_DET. According to the embodiments, if one of the bits included in the first to (M−1)^{th} read data signals DATA_RD<1:M−1> and the first to (P+1)^{th} read parity signals P_RD<1:P+1> has an error, the error sensing circuit 726 may generate the error sensing signal E_DET according to a logic level combination of the first to (P+1)^{th} syndrome signals SYN<1:P+1>. If the bits included in the first to (M−1)^{th} read data signals DATA_RD<1:M−1> and the first to (P+1)^{th} read parity signals P_RD<1:P+1> have an error, the error sensing circuit 726 may store information on locations wherein the first to (M−1)^{th} read data signals DATA_RD<1:M−1> and the first to (P+1)^{th} read parity signals P_RD<1:P+1> are stored according to the first to (P+1)^{th} syndrome signals SYN<1:P+1>.

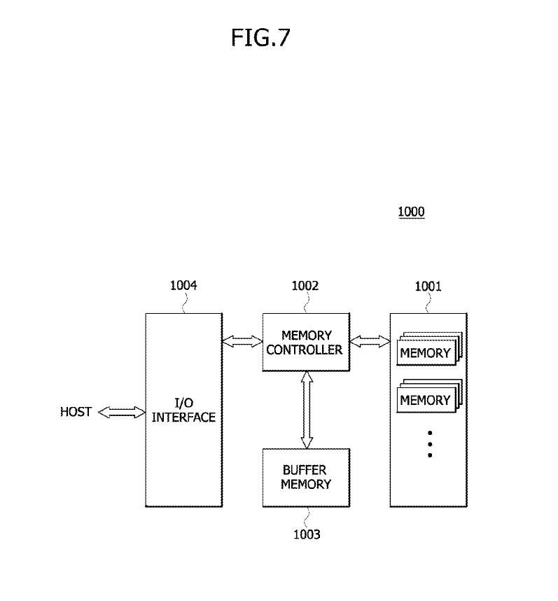

The semiconductor system illustrated in FIG. 7 may execute a test operation by using the first to (M−1)^{th} random data signals DATA_RAN<1:M−1> which are generated from the random data signal generation circuit 722 in the test mode.

The second semiconductor devices or the semiconductor systems described with reference to FIGS. 1 to 6 may be applied to an electronic system that includes a memory system, a graphic system, a computing system, a mobile system, or the like. For example, referring to FIG. 7, an electronic system 1000 according an embodiment may include a data storage circuit 1001, a memory controller 1002, a buffer memory 1003, and an input/output (I/O) interface 1004.

The data storage circuit 1001 may store data which are outputted from the memory controller 1002 or may read and output the stored data to the memory controller 1002, according to a control signal generated from the memory controller 1002. The data storage circuit 1001 may include the second semiconductor device 12 illustrated in FIG. 1 or the fourth semiconductor device 72 illustrated in FIG. 6. The data storage circuit 1001 may include a nonvolatile memory that can retain its stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage circuit 1001 or the buffer memory 1003 or for outputting the data stored in the data storage circuit 1001 or the buffer memory 1003. The memory controller 1002 may include the first semiconductor device 11 illustrated in FIG. 1 or the third semiconductor device 71 illustrated in FIG. 6. Although FIG. 7 illustrates the memory controller 1002 with a single block, the memory controller 1002 may include one controller for controlling the data storage circuit 1001 comprised of a nonvolatile memory and another controller for controlling the buffer memory 1003 comprised of a volatile memory.

The buffer memory 1003 may temporarily store the data which are processed by the memory controller 1002. The buffer memory 1003 may temporarily store the data which are outputted from or to be inputted to the data storage circuit 1001. The buffer memory 1003 may store the data, which are outputted from the memory controller 1002, according to a control signal. The buffer memory 1003 may read and output the stored data to the memory controller 1002. The buffer memory 1003 may include a volatile memory such as a dynamic random access memory (DRAM), a mobile DRAM, or a static random access memory (SRAM).

The I/O interface 1004 may physically and electrically connect the memory controller 1002 to the external device (i.e., the host). The memory controller 1002 may receive control signals and data supplied from the external device (i.e., the host) through the I/O interface 1004 and may output the data generated from the memory controller 1002 to the external device (i.e., the host) through the I/O interface 1004. The electronic system 1000 may communicate with the host through the I/O interface 1004. The I/O interface 1004 may include any one of various interface protocols such as a universal serial bus (USB), a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI) and an integrated drive electronics (IDE).

The electronic system 1000 may be used as an auxiliary storage device of the host or an external storage device. The electronic system 1000 may include a solid state disk (SSD), a USB memory, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

What is claimed is:

1. A semiconductor device comprising:
an error correction control circuit configured to generate first to (P+1)^{th} write parity signals from first to M^{th} write data signals based on a test mode signal and a read/write signal, wherein each of the first to (P+1)^{th} write parity signals is generated by performing a logical operation on at least two write data signals of the first to M^{th} write data signals; and
a signal storage circuit configured to store the first to M^{th} write data signals and the first to (P+1)^{th} write parity signals based on the read/write signal,
wherein M is a natural number, and
wherein P is a natural number.

2. The device of claim 1, wherein the error correction control circuit receives the first to (M−1)^{th} write data signals and uses an additional data signal fixed to have a first logic level as the M^{th} write data signal, based on the test mode signal while the error correction control circuit is in a test mode.

3. The device of claim 1, wherein the logical operation is an exclusive OR operation.

4. The device of claim 1,
wherein the error correction control circuit is configured to generate the first to (P+1)^{th} write parity signals based on the test mode signal and the read/write signal, if a write operation is performed while the error correction control circuit is in a test mode, and
wherein the number of the write data signals which are used in a logical operation for generating each of the first to (P+1)^{th} write parity signals is an odd number.

5. The device of claim 1,
wherein the error correction control circuit is configured to receive the first to M^{th} write data signals to generate the first to P^{th} write parity signals based on the test mode signal and the read/write signal, if a write operation is performed while the error correction control circuit is in a normal mode, and
wherein each of the first to P^{th} write parity signals is generated by performing the logical operation on at least two of the first to M^{th} write data signals.

6. The device of claim 1,
wherein the error correction control circuit is configured to generate first to (P+1)^{th} syndrome signals from the first to M^{th} read data signals and the first to (P+1)^{th} read parity signals based on the test mode signal and the read/write signal, if a read operation is performed while the error correction control circuit is in a test mode,
wherein each of the first to (P+1)^{th} syndrome signals is generated by performing a logical operation on at least two read data signals of the first to M^{th} read data signals and one read parity signal of the first to (P+1)^{th} read parity signals, and
wherein the number of the read data signals which are used in the logical operation for generating each of the first to (P+1)^{th} syndrome signals is an odd number.

7. The device of claim 6, wherein if one signal of the first to M^{th} read data signals and the first to (P+1)^{th} read parity signals has an error, the number of first logic levels included in the first to (P+1)^{th} syndrome signals is an odd number.

8. The device of claim 6, wherein if two signals of the first to M^{th} read data signals and the first to (P+1)^{th} read parity signals have errors, the number of first logic levels included in the first to (P+1)^{th} syndrome signals is an even number.

9. The device of claim 6, further comprising an error sensing circuit configured to generate an error sensing signal if the number of first logic levels included in the first to (P+1)^{th} syndrome signals is an even number.

10. The device of claim 1,
wherein the error correction control circuit is configured to generate first to P^{th} syndrome signals from first to M^{th} read data signals and first to P^{th} read parity signals based on the test mode signal and the read/write signal, if a read operation is performed while the error correction control circuit is in a normal mode, and
wherein each of the first to P^{th} syndrome signals is generated by performing a logical operation on at least two read data signals of the first to M^{th} read data signals and one read parity signal of the first to P^{th} read parity signals.

11. The device of claim 10, further comprising a data signal correction circuit configured to generate first to M^{th} correction data signals by correcting an error of the first to M^{th} read data signals according to a logic level combination of the first to P^{th} syndrome signals.

12. The device of claim 1, wherein the signal storage circuit is configured to store the first to (M−1)^{th} write data signals and the (P+1)^{th} write parity signal in a first storage region and to store the first to P^{th} write parity signals in a second storage region based on the read/write signal, if a write operation is performed while the semiconductor device is in a test mode.

13. The device of claim 1, wherein the signal storage circuit is configured to store the first to M^{th} write data signals in a first storage region and to store the first to P^{th} write parity signals in a second storage region based on the read/write signal, if a write operation is performed while the semiconductor device is in a normal mode.

14. The device of claim 1, wherein the signal storage circuit is configured to output first to (M−1)^{th} read data signals and a (P+1)^{th} read parity signal from a first storage region and to output first to P^{th} read parity signals from a second storage region based on the read/write signal, if a read operation is performed while the semiconductor device is in a test mode.

15. The device of claim 1, wherein the signal storage circuit is configured to output first to M^{th} read data signals from a first storage region and to output first to P^{th} read parity signals from a second storage region based on the read/write signal, if a read operation is performed while the semiconductor device is in a normal mode.

16. The device of claim 1, further comprising a random data signal generation circuit configured to generate first to (M−1)^{th} random data signals based on the test mode signal,
wherein the first to (M−1)^{th} random data signals are converted into the first to (M−1)^{th} write data signals.

17. The device of claim 1, wherein the error correction control circuit includes:
a data latch circuit configured to latch the first to M^{th} write data signals or first to M^{th} read data signals to generate first to M^{th} latch data signals based on the read/write signal; and
an error correction arithmetic circuit configured to perform the logical operation on the first to M^{th} latch data signals to output the logical operation result as the first to (P+1)^{th} write parity signals or configured to perform the logical operation on the first to M^{th} latch data signals and first to (P+1)^{th} read parity signals to generate first to (P+1)^{th} syndrome signals, based on the test mode signal and the read/write signal.

18. The device of claim 17, wherein the error correction arithmetic circuit includes:
an additional data signal generation circuit configured to receive the M^{th} latch data signal to generate an additional data signal based on the test mode signal;
a parity signal input control circuit configured to receive the first to (P+1)^{th} read parity signals to generate first to (P+1)^{th} read input parity signals based on the read/write signal;
an arithmetic circuit configured to receive the first to (M−1)^{th} latch data signals, the additional data signal and the first to (P+1)^{th} read input parity signals and configured to perform the logical operation on the first to (M−1)^{th} latch data signals, the additional data signal and the first to (P+1)^{th} read input parity signals to generate first to (P+1)^{th} arithmetic signals; and
a selection circuit configured to output the first to (P+1)^{th} arithmetic signals as the first to (P+1)^{th} write parity signals or the first to (P+1)^{th} syndrome signals based on the test mode signal and the read/write signal,
wherein the number of the latch data signal and the additional data signal used in the logical operation for generating each of the first to (P+1)^{th} arithmetic signals is an odd number.

19. A semiconductor device comprising:
an error correction control circuit configured to generate first to (P+1)^{th} syndrome signals from first to M^{th} read data signals and first to (P+1)^{th} read parity signals based on a test mode signal and a read/write signal, wherein each of the first to (P+1)^{th} syndrome signals is generated by performing a logical operation on at least two of the first to M^{th} read data signals and one of the first to (P+1)^{th} read parity signals, and wherein the number of the read data signals used in the logical operation for generating each of the first to (P+1)^{th} syndrome signals is an odd number; and
an error sensing circuit configured to generate an error sensing signal according to a logic level combination of the first to (P+1)^{th} syndrome signals,
wherein M is a natural number, and
wherein P is a natural number.

20. The device of claim 19, wherein if one signal of the first to M^{th} read data signals and the first to (P+1)^{th} read parity signals has an error, the number of first logic levels included in the first to (P+1)^{th} syndrome signals is an odd number.

21. The device of claim 19, wherein if two signals of the first to M^{th} read data signals and the first to (P+1)^{th} read parity signals have errors, the number of first logic levels included in the first to (P+1)^{th} syndrome signals is an even number.

22. The device of claim 19,
wherein the error correction control circuit generates the first to P^{th} syndrome signals from the first to M^{th} read data signals and first to P^{th} read parity signals based on the test mode signal and the read/write signal, if a read operation is performed while the error correction control circuit is in a normal mode, and
wherein each of the first to P^{th} syndrome signals is generated by performing a logical operation on at least two of the first to M^{th} read data signals and one of the first to P^{th} read parity signals.

23. A semiconductor system comprising:
a first semiconductor device configured to receive or output a data signal and configured to receive an error sensing signal; and
a second semiconductor device configured to generate first to (M−1)^{th} write data signals from the data signal, configured to generate an M^{th} write data signal fixed to a first logic level, configured to generate first to (P+1)^{th} write parity signals from the first to M^{th} write data signals based on a test mode signal and a read/write signal, and configured to generate the error sensing signal if an error occurs in first to (M−1)^{th} read data signals and first to (P+1)^{th} read parity signals which are outputted after the first to (M−1)^{th} write data signals and the first to (P+1)^{th} write parity signals are stored,
wherein each of the first to (P+1)^{th} write parity signals is generated by performing a logical operation on at least two of the first to M^{th} write data signals, and
wherein the number of the write data signals used in the logical operation for generating each of the first to (P+1)^{th} write parity signals is an odd number,
wherein M is a natural number, and
wherein P is a natural number.
